(19) United States
(12) Patent Application Publication
(10) Pub. No.: US 2026/0314267 A1
(43) Pub. Date: Oct. 8, 2026

(54) MAGNETIC RANDOM ACCESS MEMORY WITH FREE LAYER

(71) Applicant: Samsung Electronics Co., Ltd., Gyeonggi-do (KR)

(72) Inventors: Roman CHEPULSKYY, Santa Clara, CA (US); Dmytro APALKOV, San Jose, CA (US); Jaewoo JEONG, Los Altos, CA (US); FNU IKHTIAR, San Jose, CA (US)

(21) Appl. No.: 19/350,391

(22) Filed: Oct. 6, 2025

Related U.S. Application Data
(60) Provisional application No. 63/782,064, filed on Apr. 2, 2025.

(51) Int. Cl. H10N 50/85; H01F 10/32; H10B 61/00; H10N 50/01; H10N 50/10

(52) U.S. Cl. CPC H10N 50/85; H01F 10/329; H10B 61/10; H10B 61/20; H10N 50/01; H10N 50/10

(57) ABSTRACT

A magnetic random access memory (MRAM) is provided. The MRAM includes: a substrate, wherein the substrate includes an alkaline earth oxide; and a free layer disposed on the substrate, wherein the free layer includes an Mn-based compound or alloy.

### CROSS-REFERENCE TO RELATED APPLICATION

This application claims the priority benefit under 35 U.S.C. §119(e) of U.S. Provisional Application No. 63/782,064, filed on Apr. 2, 2025, the disclosure of which is incorporated by reference in its entirety as if fully set forth herein.

### TECHNICAL FIELD

The disclosure generally relates to magnetic random access memory (MRAM) devices. More particularly, the subject matter disclosed herein relates to improvements to free layers (FLs) in MRAM.

### BACKGROUND

Non-volatile memory technologies are widely used in modern electronic devices to retain data without power. Examples include flash memory, phase-change memory (PCM), resistive random access memory (ReRAM), and MRAM. MRAM stores data using magnetic states rather than electric charge and can provide advantages such as fast access speed, low power consumption, and high endurance. MRAM devices typically rely on magnetic tunnel junctions (MTJs), which include a free layer (FL) and a reference layer (RL) separated by a tunneling barrier. Data is stored based on the relative magnetic orientation of the FL and the RL.

### SUMMARY

Accordingly, an aspect of the disclosure provides an MRAM device having an FL composed of Mn-based materials, such as MnGa, MnAl, MnZn, MnZn₃, Mn₂CoGe, Mn₃Ge, or Mn₂CoSn, which is grown on or adjacent to a substrate, tunneling barrier, or capping layer comprising SrO or BaO.

In an embodiment, an MRAM comprises a substrate, wherein the substrate includes an alkaline earth oxide; and a free layer disposed on the substrate, wherein the free layer includes an Mn-based compound or alloy.

In an embodiment, a system comprises: an MRAM including: a first tunneling barrier layer, wherein the first tunneling barrier layer includes an alkaline earth oxide; and a free layer disposed on the first tunneling barrier layer, wherein the free layer includes an Mn-based compound or alloy.

In an embodiment, a method of fabricating an MRAM comprises: forming an oxide layer; forming a free layer on the oxide layer, wherein the free layer includes an Mn-based compound or alloy; and forming a tunneling barrier layer on the free layer, wherein at least one of the oxide layer or the tunneling barrier layer includes an alkaline earth oxide.

### BRIEF DESCRIPTION OF THE DRAWINGS

In the following section, the aspects of the subject matter disclosed herein will be described with reference to exemplary embodiments illustrated in the figures, in which:

FIG. 1 is a diagram illustrating an MRAM in which an FL is disposed on a substrate or tunneling barrier, showing how strain from SrO or BaO induces PMA and TMR, according to an embodiment;

FIG. 2 is a diagram illustrating an MRAM with an FL between a substrate/tunneling barrier and a capping layer, according to an embodiment;

FIG. 3 is a diagram illustrating an MRAM with an FL between two tunneling barriers, according to an embodiment;

FIG. 4 is a diagram illustrating a spin-transfer torque MRAM (STT-MRAM) in which an FL is incorporated with a tunneling barrier and reference layers, according to an embodiment;

FIG. 5 is a diagram illustrating an STT-MRAM including a seed layer, tunneling barrier, and reference layer stack, according to an embodiment;

FIG. 6 is a diagram illustrating a dual free-layer STT-MRAM with vertically stacked reference structures, according to an embodiment;

FIG. 7 is diagram illustrating a spin-orbit torque MRAM (SOT-MRAM) including a spin-orbit torque line, oxide layer, free layer, and tunneling barrier, according to an embodiment;

FIG. 8 includes flowcharts each illustrating a method of making an MRAM device, according to an embodiment; and

FIG. 9 is a block diagram of an electronic device, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments.

Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. The dimensions of some of the elements may be exaggerated relative to other elements for clarity. For example, the dimensions of layers and regions may be exaggerated for clarity of illustration.

Further, if considered appropriate, reference numerals may be repeated among the figures to indicate corresponding and/or analogous elements. That is, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” can include any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

“MRAM” as used herein can include a type of nonvolatile memory that stores data using magnetic states of an FL within an MTJ. Some examples of “MRAM” are STT-MRAM and SOT-MRAM, which utilize spin-polarized currents or spin-orbit effects, respectively, to switch the magnetization of the FL. “FL” as used herein can include the FL in an MTJ, which is a ferromagnetic layer whose magnetization direction can be switched to store binary information. Some examples of “FL” are magnetic layers formed of an Mn-based compound or alloy, such as MnGa, MnAl, MnZn, MnZn₃, Mn₂CoGe, Mn₃Ge, or Mn₂CoSn. Other examples of the FL may include CoFeB alloys, Heusler compounds (e.g., Co₂MnSi, Co₂FeAl), or other ferromagnetic materials such as FePt or CoPt. “Tunneling barrier” or “tunnelling barrier layer” as used herein can include an insulating layer positioned between two magnetic layers in an MTJ, through which electrons tunnel quantum mechanically, allowing resistance to vary based on the relative magnetization of the layers. Some examples of “tunneling barrier” are oxide layers such as MgO, SrO, or BaO, which may induce strain in an adjacent free layer to enhance magnetic and transport properties. Other examples of the tunneling barrier may include oxides such as Al₂O₃, TiO₂, HfO₂, or ZrO₂.

“Capping layer” as used herein can include a layer formed over a magnetic stack, to protect underlying layers from environmental exposure, assist in structural stability, or induce strain in an adjacent magnetic layer. Some examples of “capping layer” are oxide layers such as SrO or BaO, which may be selected to have a lattice parameter that induces in-plane strain in an FL to enhance PMA and TMR. In other examples, the capping layer may include oxides such as Al₂O₃, SiO₂, or TiO₂, or metallic layers such as Ta, Ru, or Pt. “Substrate” as used herein can include a base layer that provides mechanical support for the overlying magnetic stack and may also contribute to strain engineering of adjacent layers. Some examples of “substrate” are oxide crystalline layers, such as SrO or BaO, which may be selected to have a lattice parameter that induces in-plane strain in a free layer to enhance PMA and TMR. For example, the substrate may include an alkaline earth oxide. “Seed layer” as used herein can include a layer deposited below a magnetic or crystalline layer to promote desired crystal orientation, texture, or grain structure during subsequent film growth. Some examples of “seed layer” are metallic or oxide layers such as Ta, Ru, or MgO, which facilitate epitaxial or textured growth of overlying layers like the FL or reference layers in an MTJ. In other examples, the seed layer may include materials such as Pt, Ir, or Cu, or oxides such as TiN or HfO₂. “Reference layer (top or bottom)” as used herein can include a ferromagnetic layer in an MTJ having a fixed or pinned magnetization direction. Some examples of “reference layer” are CoFeB, CoPt, or other ferromagnetic materials that may be part of a synthetic antiferromagnetic (SAF) structure when coupled through a spacer layer such as Ru. In other embodiments, the reference layer may include materials such as FePt, NiFe, or multilayered Co/Pt or Co/Pd stacks. “Spacer” as used herein can include a nonmagnetic layer disposed between two ferromagnetic layers to control their magnetic coupling. Some examples of “spacer” are metallic layers such as Ru, Rh, or Ir, which may mediate Ruderman-Kittel-Kasuya-Yosida (RKKY) interactions between adjacent magnetic layers.

For the sake of brevity, techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein but known to a person of ordinary skill in the art. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), etc. Semiconductor doping is the modification of electrical properties by doping, e.g., transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the structures that make up an IC device, lithography and etch pattern transfer steps are repeated multiple times. Each pattern being printed on the wafer is aligned to the previously formed patterns and slowly the conductors, insulators and selectively doped regions are built up to form the final device.

The performance of MRAM generally depends on two properties of the FL: TMR, which affects readout signal strength, and PMA, which contributes to data stability and scalability. Various materials have been studied for their potential to improve these aspects of MRAM devices.

For example, different techniques have been explored to improve MRAM characteristics, including optimization of the material composition or crystalline orientation of the FL, or the use of tunneling barrier materials to enhance spin filtering.

Additional factors that can influence MRAM performance include the strain state of the FL, the lattice relationship between layers, and the choice of substrates, barriers, or capping layers. Variations in these parameters can impact the properties of the FL, affecting the ability of MRAM devices to achieve desired levels of stability and signal contrast.

The description of these technologies and approaches is provided for general background and is not intended to constitute an admission that such technologies or approaches are prior art with respect to the present disclosure.

Embodiments of the present disclosure provide MRAM devices that utilize an FL designed to simultaneously exhibit high TMR and PMA. The FL can be formed from Mn-based magnetic materials, such as MnGa, MnAl, MnZn, MnZn₃, Mn₂CoGe, Mn₃Ge, or Mn₂CoSn, which exhibit enhanced magnetic and transport properties under certain in-plane stress conditions. In the embodiments, the FL can be grown on or adjacent to a substrate, tunneling barrier layer, or capping layer composed of materials such as SrO or BaO. These surrounding layers cany be selected for their low lattice parameters, which induce strain in the FL through lattice matching during growth.

This strain-based approach shifts the FL into a stress window where both TMR and PMA can be optimized. By selecting combinations of materials that generate the appropriate in-plane lattice mismatch, the embodiments can achieve improved spin polarization, magnetic stability, and overall device performance without relying solely on barrier or composition tuning. The resulting MRAM structures are well-suited for advanced memory applications, including STT and SOT switching architectures.

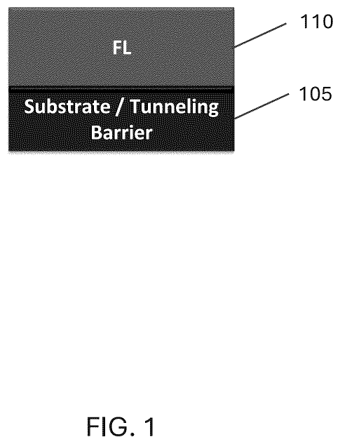

FIG. 1 illustrates an MRAM in which an FL is disposed on a substrate or tunneling barrier, showing how strain from SrO or BaO induces PMA and TMR, according an embodiment. The MRAM may include an FL 110 disposed on a substrate or tunneling barrier 105. The FL 110 may include a magnetic material selected from Mn-based alloys, including but not limited to MnGa, MnAl, MnZn, MnZn₃, Mn₂CoGe, Mn₃Ge, or Mn₂CoSn. For example, the FL 110 may include an Mn-based compound or alloy. In other embodiments, the FL 110 may comprise ferromagnetic alloys such as CoFeB, high-anisotropy alloys such as FePt or CoPt, or Heusler compounds including Co₂MnSi or Co₂FeAl, which can support high spin polarization and stable magnetic switching. The FL 110 may have a thickness in a range from approximately 0.5 nanometers to 7 nanometers, although other thicknesses may also be used. The particular thickness may vary depending on material selection, device architecture, or process conditions, and can be optimized based on experimental or computational results. For example, the thickness range may be selected to support both magnetic stability and efficient switching, while maintaining PMA in the presence of strain.

The substrate or tunneling barrier 105 may include a material having a relatively low in-plane lattice parameter, such as SrO or BaO. For example, the substrate or tunneling barrier 105 may include an alkaline earth oxide. In other embodiments, the substrate or tunneling barrier 105 may comprise other crystalline oxides or insulating materials, including MgO, Al₂O₃, TiO₂, HfO₂, or ZrO₂, which can provide structural support, lattice matching, and spin-filtering functionality in an MRAM device. When the FL 110 is grown on the substrate or tunneling barrier 105, the resulting lattice mismatch can induce in-plane strain in the FL 110. This strain may cause the material of the FL 110 to enter a stress state in which it simultaneously exhibits high TMR and PMA. The use of coherent lattice matching between the FL 110 and the underlying layer, e.g., the substrate or tunneling barrier 105, can provide precise strain control through material selection, without requiring modification of the composition of the FL 110 itself.

In an embodiment, the substrate 105 may serve as a mechanical support, with a separate tunneling barrier layer disposed between it and the FL 110. In another embodiment, substrate 105 may function as the tunneling barrier if it possesses suitable electrical and crystallographic properties. This configuration supports spin-polarized tunneling and contributes to efficient and stable data storage in the MRAM.

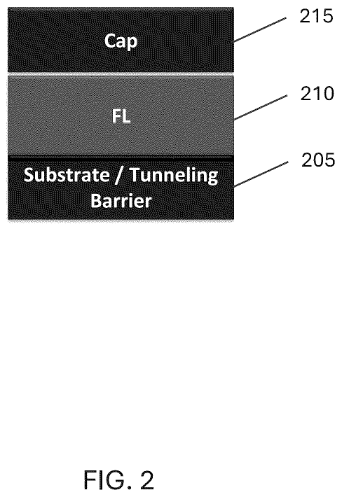

FIG. 2 illustrates an MRAM with an FL between a substrate/tunneling barrier and a capping layer, according an embodiment. In FIG. 2, an FL 210 may be disposed between a substrate or tunneling barrier 205 and a capping layer 215. The FL 210 may include a magnetic material, such as MnGa, MnAl, MnZn, MnZn₃, Mn₂CoGe, Mn₃Ge, or Mn₂CoSn, and have a thickness in the range of approximately 0.5 nanometers to 7 nanometers. The material and thickness of the FL 210 are selected to enable the device to exhibit both PMA and TMR when strain is applied. For example, the FL 210 may also comprise ferromagnetic alloys such as CoFeB, high-anisotropy alloys such as FePt or CoPt, or Heusler compounds including Co₂MnSi or Co₂FeAl, and the particular thickness of the FL 210 may vary depending on material selection, device architecture, or process conditions.

The capping layer 215 and the substrate or tunneling barrier 205 may each be formed of materials having relatively low in-plane lattice parameters, such as SrO or BaO. In other embodiments, these layers may include oxides such as MgO, Al₂O₃, SiO₂, TiO₂, or HfO₂, which can serve as protective or insulating layers while also contributing to lattice matching and strain engineering in MRAM devices. These layers are configured to induce in-plane strain in the FL 210 through coherent lattice matching. At least one of the capping layer 215 or the substrate or tunneling barrier 205 may be selected to have a lattice parameter that causes the FL 210 to enter a stress regime where both PMA and TMR are enhanced, based on ab-initio modeling, for example. The ability to tune strain from either side of the FL 210 can provide design flexibility and improves the robustness of the magnetic and transport performance.

In an embodiment, the capping layer 215 may perform additional functions, such as protecting the magnetic stack from environmental degradation, acting as a diffusion barrier, or supporting subsequent layer deposition. The substrate or tunneling barrier 205 may serve either as a mechanical support or as a functional tunnel barrier, depending on its composition and electrical properties. This structure enables precise control of strain and magnetic orientation within the FL 210, resulting in stable, high-performance MRAM operation.

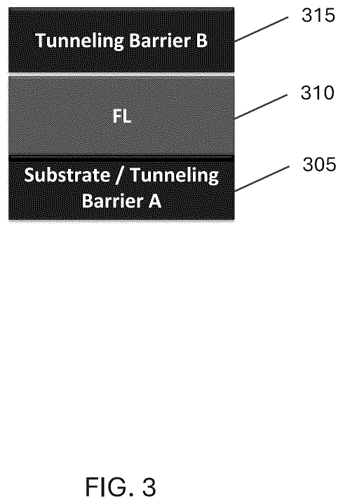

FIG. 3 illustrates an MRAM with an FL between two tunneling barriers, according an embodiment. In FIG. 3, an FL 310 is disposed between a substrate or first tunneling barrier 305 and a second tunneling barrier 315. The FL 310 may include a magnetic material selected from Mn-based alloys, such as MnGa, MnAl, MnZn, MnZn₃, Mn₂CoGe, Mn₃Ge, or Mn₂CoSn. In other embodiments, the FL 310 may comprise ferromagnetic alloys such as CoFeB, high-anisotropy alloys such as FePt or CoPt, or Heusler compounds including Co₂MnSi or Co₂FeAl. The FL 310 may have a thickness in a range from approximately 0.5 nanometers to 7 nanometers, which supports both switching efficiency and the maintenance of PMA under strain, and the particular thickness of the FL 310 may vary depending on material selection, device architecture, or process conditions.

At least one of the substrate or first tunneling barrier 305 or the second tunneling barrier 315 may be formed of a material having a low in-plane lattice parameter, such as SrO or BaO, which induces in-plane strain in the FL 310 during or after deposition. In other embodiments, these layers may include oxides such as MgO, Al₂O₃, SiO₂, TiO₂, or HfO₂. This strain may be configured to place the FL 310 in a stress regime where both high TMR and strong PMA can be simultaneously achieved. The structure allows for strain tuning from both sides of the FL 310, which improves control over magnetic orientation and spin transport properties in the MRAM.

The substrate or first tunneling barrier 305 and the second tunneling barrier 315 may also function electrically as spin-filtering layers, supporting spin-polarized tunneling and enabling resistance contrast between parallel and antiparallel magnetic configurations. In an embodiment, both the substrate or first tunneling barrier 305 and the second tunneling barrier 315 may include SrO or BaO, while in other embodiments only one of them may be selected to induce the desired strain, depending on the intended device performance and fabrication compatibility. This configuration supports enhanced device efficiency, reliability, and integration flexibility in advanced MRAM technologies.

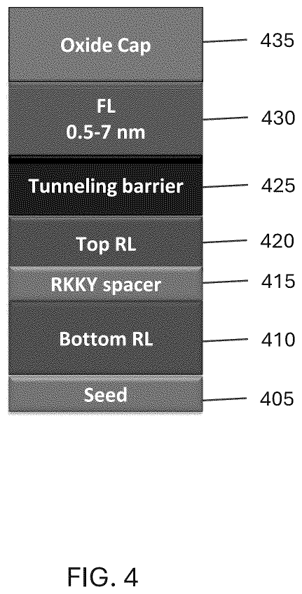

FIG. 4 is a diagram illustrating an STT-MRAM in which an FL is incorporated with a tunneling barrier and reference layers, according to an embodiment. The illustrated structure includes an FL 430 disposed on a tunneling barrier 425, forming the core of an MTJ. The FL 430 may include a magnetic material selected from Mn-based alloys such as MnGa, MnAl, MnZn, MnZn₃, Mn₂CoGe, Mn₃Ge, or Mn₂CoSn, and have a thickness in the range of approximately 0.5 nanometers to 7 nanometers. In other embodiments, the FL 430 may comprise other ferromagnetic or intermetallic materials, including CoFeB, FePt, CoPt, or Heusler compounds such as Co₂MnSi or Co₂FeAl, which can provide high spin polarization and stable switching behavior. The thickness of the FL 430 may be selected based on magnetic stability and switching efficiency, and may vary depending on the specific material system and device design. The FL 430 is switchable and operates with PMA and TMR when strained appropriately.

Beneath the tunneling barrier 425 may be a top reference layer 420 and a bottom reference layer 410, which together provide a fixed magnetic orientation for comparison with the FL 430. The top and bottom reference layers 420 and 410 may be ferromagnetic and configured to form an SAF structure. A spacer 415 may be disposed between the top and bottom reference layers 420 and 410 and may include a nonmagnetic metal such as ruthenium, enabling antiferromagnetic exchange coupling to stabilize the magnetization of the reference layer stack. The spacer 415 may be an RKKY spacer. In some embodiments, the spacer 415 may include nonmagnetic metallic layers such as Ru, Rh, or Ir, while in other embodiments alternative spacer materials may be used to control magnetic coupling strength and stability.

The reference layer stack may be supported by a seed layer 405, which promotes crystalline growth and proper orientation of the magnetic layers, and is formed below a substrate. Above the FL 430, an oxide capping layer 435 is provided. The oxide capping layer 435 may protect the stack from environmental degradation and may also function as a stress-inducing layer when formed from materials with a low in-plane lattice parameter, such as SrO or BaO. In other embodiments, the oxide capping layer may include materials such as Al₂O₃, SiO₂, TiO₂, or HfO₂.

At least one of the tunneling barrier 425 or the oxide capping layer 435 may be configured to induce in-plane strain in the FL 430. This strain places the FL 430 within a stress window in which both PMA and TMR are simultaneously enhanced. This strain-engineered MTJ structure enables efficient, stable magnetization switching and is well suited for high-performance MRAM applications.

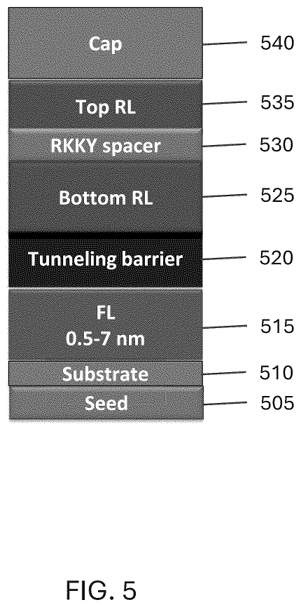

FIG. 5 is a diagram illustrating an STT-MRAM including a seed layer, tunneling barrier, and reference layer stack, according to an embodiment. In FIG. 5, an FL 515 may be positioned below a tunneling barrier 520. The FL 515 may include a magnetic material selected from Mn-based alloys such as MnGa, MnAl, MnZn, MnZn₃, Mn₂CoGe, Mn₃Ge, or Mn₂CoSn, and have a thickness in the range of approximately 0.5 nanometers to 7 nanometers. The material and thickness of the FL 515 may correspond to those described for FIGS. 1-4. The FL 515 may be grown on a seed layer 505, which promotes crystallographic texture and magnetic anisotropy in the FL 515. A substrate 510 may be disposed above the seed layer 505 and provides mechanical support for the device.

The tunneling barrier 520 may be disposed on the FL 515 and may include MgO, SrO, or BaO. In other embodiments, the tunneling barrier 520 may comprise other insulating oxides such as Al₂O₃, TiO₂, HfO₂, or ZrO₂. The tunneling barrier 520 may be configured to support spin-polarized tunneling and establish resistance contrast based on the relative orientation of the FL 515 and the magnetic layers above it. A bottom reference layer 525 may be disposed on the tunneling barrier 520 and provides a fixed magnetization for spin torque operation. The bottom reference layer 525 may be magnetically coupled to a top reference layer 535 through a RKKY spacer 530, which may include a nonmagnetic metal such as ruthenium and enables antiferromagnetic exchange coupling between the bottom and top reference layers 525 and 535.

A capping layer 540 may be disposed over the reference layer stack. The capping layer 540 may protect the magnetic layers from environmental exposure and may also be selected to assist in maintaining structural integrity or magnetic stability. In some embodiments, the capping layer 540 may be formed of an oxide or other insulating material.

At least one of the layers adjacent to the FL 515, such as the substrate 510 or the tunneling barrier 520, may include a material with a low in-plane lattice parameter, such as SrO or BaO, and be configured to induce in-plane strain in the FL 515. This strain enhances the magnetic properties of the FL 515, allowing it to simultaneously exhibit PMA and high TMR.

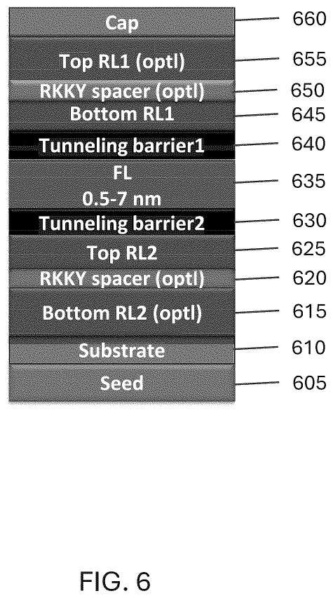

FIG. 6 is a diagram illustrating a dual free-layer STT-MRAM with vertically stacked reference structures, according to an embodiment. In other words, FIG. 6 illustrates an MRAM device having a vertically stacked architecture that includes dual reference layer structures positioned on opposite sides of a central free layer and tunneling barrier region. In FIG. 6, a substrate 610 may be formed on a seed layer 605, and supports the growth of an optional bottom reference layer 2 (bottom RL2) 615, which may serve as part of an SAF stack. An optional RKKY spacer 620 may be disposed on the bottom RL2 615 and may enable antiferromagnetic coupling to an overlying top reference layer 2 (top RL2) 625. These layers together form the lower magnetic reference structure.

A second tunneling barrier 630 may be disposed on the top RL2 625 and provides spin-dependent transport between the lower magnetic reference structure and an overlying FL 635. The FL 635 may include a magnetic material selected from MnGa, MnAl, MnZn, MnZn₃, Mn₂CoGe, Mn₃Ge, or Mn₂CoSn, and have a thickness in the range of approximately 0.5 nanometers to 7 nanometers. The material and thickness of the FL 615 may correspond to those described for FIGS. 1-5. The FL 635 may be a magnetically switchable layer that exhibits both PMA and high TMR when subjected to appropriate in-plane strain. A first tunneling barrier 640 may be disposed above the FL 635 and can enable spin-polarized tunneling between the FL 635 and the upper reference layer stack.

The upper reference stack may include a bottom reference layer 1 (bottom RL1) 645 disposed on the first tunneling barrier 640. In some embodiments, the bottom RL1 645 may be magnetically coupled to an optional top reference layer 1 (top RL1) 655 through an optional RKKY spacer 650. These layers form an upper SAF structure that mirrors or complements the lower magnetic reference structure. A cap layer 660 may be disposed over the top RL1 655 and may function as a protective layer and/or stress-engineering layer depending on its composition.

At least one of the tunneling barriers 630 or 640, or optionally the cap 660, may be formed of a material having a low in-plane lattice parameter, such as SrO or BaO. These materials are selected to induce in-plane strain in the FL 635, placing it within a stress window to simultaneously enhance both PMA and TMR. This dual-reference, strain-engineered architecture enables improved symmetry, stability, and performance in STT-MRAM devices.

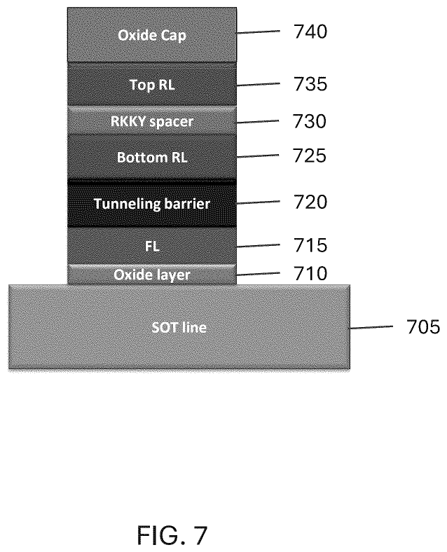

FIG. 7 is diagram illustrating an SOT-MRAM including a spin-orbit torque line, oxide layer, free layer, and tunneling barrier, according to an embodiment. In particular, FIG. 7 illustrates an SOT-MRAM in which current applied through an SOT line 705 generates a spin current that switches the magnetization of an FL 715 via spin-orbit interaction. The SOT line 705 may be formed of a material configured to produce a large spin Hall effect (SHE) or Rashba-Edelstein effect.

Example materials for the SOT line 705 include heavy metals such as Ta, W, Pt, Hf, or alloys and multilayers of W, Pt, Tb, Bi, Hf, Zr, Ag, Au, Si, Cu, Cr, V, Mo, including, e.g., WHf, Au/Si, or oxidized variants like W/Ox/W/Ox/W/Ox. Additional candidates include topological insulators such as BiTe, BiSe, TlBiTe, TlBiSe, SbTeS, BiTeS, BiTeSe, GeSbTe, SnSbTe, GeBiTe, SnBiTe, BiSb, and BiSbSe, as well as conductive oxides like IrO₂ and SrIrO₃, and antiferromagnetic or ferrimagnetic materials of the form AxB1−x, where A is Ir, Pt, Pd, or Rh, and B is Mn or Fe, with 0<x<1.

An oxide layer 710 may be formed on the SOT line 705. The oxide layer 710 may be configured to suppress current shunting and improve the spin Hall angle (SHA). The oxide layer 710 may have a thickness in the range of approximately 0.4 nanometers to 15 nanometers and may include SrO, BaO, MgO, or multilayered oxide stacks. The oxide layer 710 may also exhibit partial oxidation or interface engineering to enhance resistivity and spin injection efficiency.

An FL 715 is formed on the oxide layer 710. The FL 715 may include a magnetic material selected from MnGa, MnAl, MnZn, MnZn₃, Mn₂CoGe, Mn₃Ge, or Mn₂CoSn, and have a thickness in the range of 0.5 nanometers to 7 nanometers. The material and thickness of the FL 715 may correspond to those described for FIGS. 1-6. The FL 715 is configured to exhibit PMA and high TMR when appropriately strained. A tunneling barrier 720 is formed on the FL 715 and may include SrO, BaO, or MgO to enable spin-polarized tunneling and maintain coherent lattice matching with the FL 715.

Above the tunneling barrier 720, a reference layer stack may be formed, including a bottom reference layer 725, an RKKY spacer 730, and a top reference layer 735. These layers may include ferromagnetic materials and are optionally configured as an SAF pair. The RKKY spacer 730 may include materials such as ruthenium and be configured to establish antiferromagnetic exchange coupling between the bottom and top reference layers 725 and 735, improving magnetic stability and minimizing dipolar field interference.

An oxide capping layer 740 may be disposed above the reference layer stack and may protect the device from environmental exposure or assist with structural or strain stability. At least one of the tunneling barrier 720 or oxide capping layer 740 includes a material such as SrO or BaO, which has a low in-plane lattice parameter and is configured to induce in-plane strain in the FL 715. This strain places the FL 715 into a performance regime that supports both strong PMA and enhanced TMR. In other embodiments, the tunneling barrier 720 or oxide capping layer 740 may include alternative oxides such as MgO, Al₂O₃, TiO₂, or HfO₂.

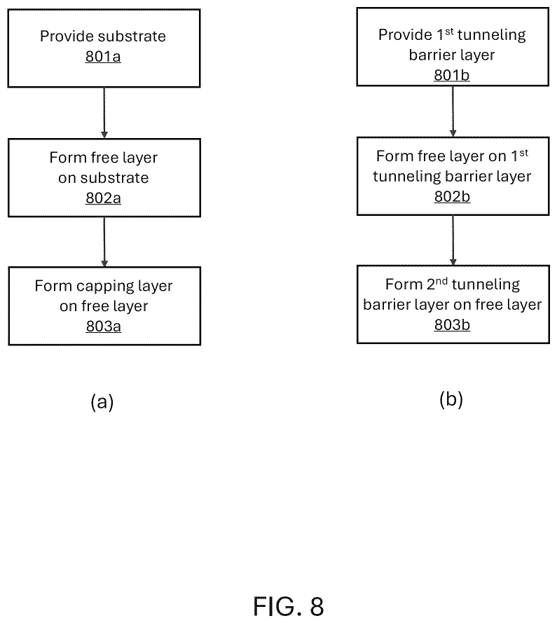

FIG. 8 includes flowcharts each illustrating a method of making an MRAM device, according to an embodiment.

Referring to FIG. 8(a), the method may include providing a substrate including SrO or BaO (step 801a). The substrate may serve as a mechanical support for subsequent layers and may also establish a lattice relationship with the FL due to its relatively low in-plane lattice parameter.

The method may further include forming an FL on the substrate (step 802a). The FL may include a magnetic material such as MnGa, MnAl, MnZn, MnZn₃, Mn₂CoGe, Mn₃Ge, or Mn₂CoSn. In some embodiments, the FL may have a thickness in the range of about 0.5 nanometers to about 7 nanometers. The thickness may be selected to balance thermal stability, magnetic anisotropy, and switching efficiency. The FL may be deposited using methods such as molecular beam epitaxy (MBE), sputtering, or atomic layer deposition (ALD).

The method may then include forming a capping layer on the FL (step 803a). The capping layer may be formed of an oxide material, such as SrO or BaO, which has a low in-plane lattice parameter that can induce strain in the FL to enhance PMA and TMR. In other embodiments, the capping layer may include materials such as Al₂O₃, SiO₂, TiO₂, or HfO₂, which can serve as protective passivation layers and contribute to structural stability of the MRAM device.

Referring to FIG. 8(b), the method may include forming a first tunneling barrier layer including SrO or BaO (step 801b). The first tunneling barrier may function as an insulating layer that supports spin-polarized tunneling and may also provide lattice matching with a subsequently deposited FL.

The method may further include depositing an FL on the first tunneling barrier layer (step 802b). The FL may include a magnetic material such as MnGa, MnAl, MnZn, MnZn₃, Mn₂CoGe, Mn₃Ge, or Mn₂CoSn. The FL may have a thickness in the range of about 0.5 nanometers to about 7 nanometers.

The method may then include forming a second tunneling barrier layer on the FL (step 803b). The second tunneling barrier may include an oxide such as SrO or BaO to induce strain in the FL, or in other embodiments, may include alternative insulating oxides such as MgO, Al₂O₃, TiO₂, or HfO₂ to provide additional spin-filtering and structural functionality.

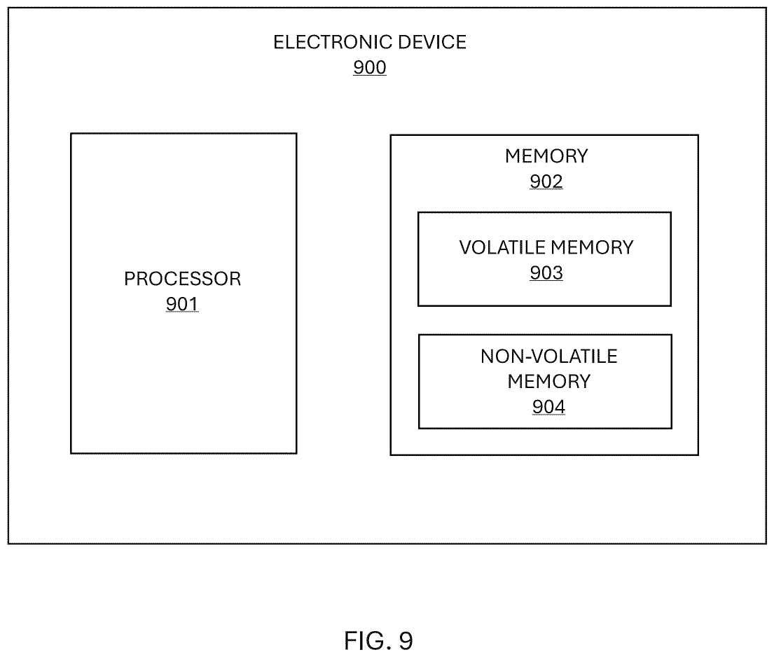

FIG. 9 is a block diagram of an electronic device, according to an embodiment.

Referring to FIG. 9, an electronic device 900, e.g., a user equipment (UE) or a mobile terminal, includes a processor 901 and a memory 902. Although not illustrated in FIG. 9, dependent on the type of the electronic device 900, the electronic device 900 may include various additional components, such as an input device, a sound output device, a display device, an audio module, a sensor module, an interface, a haptic module, a camera module, a power management module, a battery, a communication module, a subscriber identification module (SIM), and/or an antenna module.

The processor 901 may execute, for example, software (e.g., a program) to control at least one other component (e.g., a hardware or a software component) of the electronic device 900, and may perform various data processing or computations. As at least part of the data processing or computations, the processor 901 may load a command or data received from another component in volatile memory 903, process the command or the data stored in the volatile memory 903, and store resulting data in non-volatile memory 904. The processor 901 may include a main processor (e.g., a central processing unit (CPU) or an application processor, and an auxiliary processor (e.g., a graphics processing unit (GPU), an image signal processor (ISP), a sensor hub processor, or a communication processor (CP)) that is operable independently from, or in conjunction with, the main processor.

The memory 902 may store various data used by at least one component (e.g., the processor 901) of the electronic device 900. The various data may include, for example, software (e.g., the program) and input data or output data for a command related thereto. The memory 902 may include the volatile memory 903 or the non-volatile memory 904. The non-volatile memory 904 includes a memory cell/unit of an MRAM product, e.g., as illustrated in FIGS. 1-8.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

While the present disclosure has been shown and described with reference to certain embodiments thereof, it will be understood by those skilled in the art that various changes in form and details may be made therein without departing from the spirit and scope of the disclosure as defined by the appended claims and their equivalents.

What is claimed is:

1. A magnetic random access memory (MRAM) comprising:
a substrate, wherein the substrate includes an alkaline earth oxide; and
a free layer disposed on the substrate, wherein the free layer includes an Mn-based compound or alloy.

2. The MRAM of claim 1, wherein the alkaline earth oxide includes at least one of SrO or BaO.

3. The MRAM of claim 1, wherein the Mn-based compound or alloy includes at least one of MnGa, MnAl, MnZn, MnZn3, Mn2CoGe, Mn3Ge or Mn2CoSn.

4. The MRAM of claim 1, further comprising a capping layer disposed on the free layer.

5. The MRAM of claim 1, further comprising a capping layer disposed on the free layer, wherein the capping layer includes at least one of SrO or BaO.

6. The MRAM of claim 1, further comprising a tunneling barrier layer disposed on the free layer.

7. The MRAM of claim 1, further comprising a tunneling barrier layer disposed on the free layer, wherein the tunneling barrier layer includes at least one of SrO or BaO.

8. The MRAM of claim 1, further comprising:
a tunneling barrier layer disposed on the free layer;
a seed layer on which the substrate is disposed;
a bottom reference layer disposed on the tunneling barrier layer;
a spacer disposed on the bottom reference layer;
a top reference layer disposed on the spacer; and
a capping layer disposed on the top reference layer.

9. A system comprising:
a magnetic random access memory (MRAM) including:
a first tunneling barrier layer, wherein the first tunneling barrier layer includes an alkaline earth oxide; and
a free layer disposed on the first tunneling barrier layer, wherein the free layer includes an Mn-based compound or alloy.

10. The system of claim 9, wherein the alkaline earth oxide includes at least one of SrO or BaO.

11. The system of claim 9, wherein the Mn-based compound or alloy includes at least one of MnGa, MnAl, MnZn, MnZn3, Mn2CoGe, Mn3Ge or Mn2CoSn.

12. The system of claim 9, wherein the MRAM further comprises a capping layer disposed on the free layer.

13. The system of claim 8, wherein the MRAM further comprises a capping layer disposed on the free layer, wherein the capping layer includes at least one of SrO or BaO.

14. The system of claim 9, wherein the MRAM further comprises:
a seed layer;
a bottom reference layer disposed on the seed layer;
a spacer disposed on the bottom reference layer;
a top reference layer disposed on the spacer, wherein the first tunneling barrier layer is disposed on the top reference layer.

15. The system of claim 9, wherein the MRAM further comprises a second tunneling barrier layer disposed on the free layer.

16. A method of fabricating a magnetic random access memory (MRAM) comprising:
forming an oxide layer;
forming a free layer on the oxide layer, wherein the free layer includes an Mn-based compound or alloy; and
forming a tunneling barrier layer on the free layer, wherein at least one of the oxide layer or the tunneling barrier layer includes an alkaline earth oxide.

17. The method of claim 16, wherein the Mn-based compound or alloy includes at least one of MnGa, MnAl, MnZn, MnZn3, Mn2CoGe, Mn3Ge or Mn2CoSn.

18. The method of claim 16, wherein the alkaline earth oxide includes at least one of SrO or BaO.

19. The method of claim 16, wherein the oxide layer is disposed on a spin-orbit torque line (SOT).
